(19) United States
(12) Patent Application Publication
(10) Pub. No.: US 2006/0049721 A1
(43) Pub. Date: Mar. 9, 2006

(54) Device for ultrasonic inspection

(76) Inventor: Horst Kuehnicke, Dresden (DE)

Correspondence Address: JACOBSON HOLMAN PLLC, 400 SEVENTH STREET N.W., SUITE 600, WASHINGTON, DC, 20004, US

(21) Appl. No.: 11/215,125

(22) Filed: Aug. 31, 2005

(30) Foreign Application Priority Data
Sep. 1, 2004 (DE) 10 2004 043 180.9

(51) Int. Cl. H01L 41/08

(52) U.S. Cl. 310/334

(57) ABSTRACT

The invention relates to a device for ultrasonic inspection which can be used preferably for the non-destructive inspection of bodies, e.g. component parts, by means of ultrasonic waves, and in universal manner for the inspection of various bodies/component parts. It is an object of the invention to be able performing non-destructive inspection of bodies by means of ultrasonic waves cost-effective, and to achieve simultaneously ways for a flexible application on most differently formed and dimensioned bodies. As a result, the device according to the invention is formed such that an ultrasonic wave transmitting and receiving element is housed inside a testing head mountable on the surface of a body. The ultrasonic wave transmitting and receiving element and/or an acoustic element reflecting, focussing and/or deflecting an emitted beam of ultrasonic waves is pivoted about at least one axis of rotation by means of at least one actuator, and/or is travelling laterally along at least one axis.

The invention relates to a device for ultrasonic inspection which can be preferably used for non-destructive testing of bodies, e.g. component parts by means of ultrasonic waves, and which can be used in a universal manner for testing various bodies/component parts. At the same time, the detection of defects but also inhomogeneities of material as well as the recognition of positions of boundary layers within such bodies/component parts is possible. In particular, application can be advantageously carried out with bulky bodies/component parts. Thus, e.g. applications for the quality assurance in the industrial branches of aerospace industry, vehicle engineering, metallurgy, machinery and plant construction, electrical engineering and electronics are possible.

In accordance with the prior art, during the non-destructive inspection complex systems are used for bulky and thick-walled component parts by means of which ultrasonic waves are used with predetermined acoustic irradiation angles as well as beams of ultrasonic waves having a predetermined focal point within component parts. In order to be capable of implementing detection with various acoustic irradiation angles, and to be capable of implementing different positions of focal points within a component part, either a plurality of so called ultrasonic testing heads formed in a different manner have to be used for one component part, because of that the cost for the provision of such ultrasonic testing heads does not have an adverse effect only, however, but also the required time involved for the non-destructive inspection in component parts is increased accordingly.

Alternatively, systems which are designated as “transceiver array probes” are usable for the non-destructive inspection. A three-dimensional detection inside of component parts is possible with these systems. They are allowed to be positioned in an automated manner relative to the respective component part and can carry out a relative motion along the surface of component parts such that the time involved for a non-destructive inspection can be reduced compared with the previously mentioned application of a plurality of ultrasonic testing heads.

The transceiver array probes utilize a phase-shifted drive of an ultrasonic transmitting and receiving element separated into individual elements. As a result, with the individual elements different acoustic irradiation angles and positions of focal points can be implemented. At the same time, the individual elements are activated in a time-discrete and successive manner, and correspondingly the detection is also carried out in this way.

For activating of individual elements, piezoelectric transducers each being allocated thereto are available which will then be activated with individual high voltage impulses. On that occasion, considerable problems are caused in particular by the required high voltages having adequate frequencies which are in the megahertz range. Accordingly, a great number of high voltage high frequency connecting lines to the respective piezoelectric actuators is required wherein electric contacting of such high voltage high frequency connecting lines with the piezoelectric actuators is already lavish. In addition, increased effort for the electronic drive has notched up.

As a result, it is an object of the invention to propose ways by means of which a non-destructive inspection of bodies is achievable in a cost-effective manner by means of ultrasonic waves, and also to propose possibilities for a flexible use on most differently shaped and dimensioned bodies.

According to the invention, this object is solved with a device comprising the features of claim 1. Advantageous embodiments and improvements of the invention can be achieved with the features designated in the subordinate claims.

The device according to the invention is then formed such that an ultrasonic transmitting and receiving element is housed in an ultrasonic testing head mountable on the surface of a component part. Ultrasonic waves are emitted substantially as a collimated beam which should have a low divergence, if possible, from the ultrasonic transmitting and receiving element, and which is directed upon the surface of the body. By means of mechatronic control elements it is allowed to operate with high shot repetition frequencies of up to appr. 1 kHz, at least with 750 Hz. In this connection, the low volume and the mass of the testing head, and also of the individual elements each to be moved and pivoted, respectively, have an advantageous effect on the achievable largely reduced test time for a component part.

Thus, inspection can be performed with a sufficient detection accuracy within a time period being smaller than 100 ms.

The entire volume of a testing head may be smaller than 2 cm³.

On the device according to the invention there is provided an actuator for selective variation and influence, respectively, of discriminatingly predeterminable acoustic irradiation angles, and/or the position of the respective focal point of an ultrasonic wave beam.

Such an actuator is allowed to affect right on the ultrasonic transmitting and receiving element, and to cause a motion thereon. As a result, the ultrasonic transmitting and receiving element can be pivoted at least about one axis of rotation such that different acoustic irradiation angles can be adjusted, and detection at different acoustic irradiation angles can be performed. However, with at least one actuator, solely or additionally, a translational motion along at least one axis of the ultrasonic transmitting and receiving element can also be achieved by means of the respective displacement thereof.

In a second alternative embodiment according to the invention, inside the testing head an additional acoustic element can also be located by means of which the emitted and reflected ultrasonic waves will be influenced in their beam positioning and beam shaping because of appropriate reflection, focussing and/or deflection.

Such an acoustic element is then arranged within the beam path of the ultrasonic waves between the respective component part surface and the ultrasonic transmitting and receiving element such that the emitted and reflected ultrasonic waves impinge upon such an acoustic element, and will be reflected on a surface of the acoustic element or else will be diffracted on boundary layers of acoustic elements during the penetration thereof.

Thus, for example, defined influence of various acoustic irradiation angles can be achieved by means of pivoting at least about one axis of rotation of an acoustic element, since in this way the incident angle and the angle of reflection of the emitted and also retroreflective ultrasonic waves can be altered.

In the simplest form, such a reflecting acoustic element may have a planar surface.

However, it is also possible for such acoustic elements to be used with a concavely curved surface such that focussing of ultrasonic waves towards the interior of the respective component part can be achieved in addition to the reflection.

Having a concavely curved surface of such acoustic elements, providing a spherical curvature of the respective surface can be particularly advantageous if these acoustic elements can be pivoted at least about one axis of rotation by means of an actuator. Because of that, the distance of the focal point of ultrasonic waves emitted by the ultrasonic transmitting and receiving element can be changed and maintained constant at different acoustic irradiation angles as well.

But such reflecting acoustic elements having a curved surface are also allowed to be shifted laterally along an axis by means of which a selective variation of the respective position of the focal point can be achieved.

However, acoustic elements with one actuator which affects thereon can also be used wherein the respective ultrasonic waves will be diffracted on the respective boundary layers during penetration thereof. These, for example, are so called acoustic lenses or rather acoustic prisms.

With acoustic lenses it is allowed, by analogy with electromagnetic radiation with optical lenses, to change the position of the focal point by means of adequate laterally shifting.

With acoustic prisms, when shifted laterally which preferably should take place orthogonally toward the alignment of the acoustic axis of the emitted acoustic waves, it is allowed to selectively achieve defined and also adequately differentiated acoustic irradiation angles of ultrasonic waves in the/that respective body/component part.

The so-called voice coil actuators can be used particularly preferred as actuators since these have very small time constants, and enable relatively high regulating powers and moments, respectively, and are addressable with high precision with respect to the adequate obtainable paths and angles should the occasion arise, such that a very accurate motion of the respective ultrasonic transmitting and receiving element and acoustic element and acoustic element, respectively, relative to the respective shifting travels and pivoting angles is achievable.

Accordingly, variations of the acoustic irradiation angles or rather of the position of the respective focal point can be performed with a frequency of appr. 1 kHz such that a discriminating detection can be carried out in time intervals in the range of appr. 1 ms with different acoustic irradiation angles and on different positions of focal points, respectively.

Such voice coil actuators or rather other suitable actuators are then allowed to affect right on the respective ultrasonic transmitting and receiving element and the respective acoustic element, respectively. However, in some cases it may be advantageous to provide a spatial separation and to implement the mechanical connector between the actuator and acoustic element, and ultrasonic transmitting and receiving element, respectively, such as through a lever member wherein a flexible joint is of advantage. Thus, a lever member can be formed such as in the form of an elbow lever which is rotatably supported about an axis.

But the mechanical connector may also be achieved through various appropriate gear designs. Then, with the lever members and gears, respectively, a magnification but also a reduction of obtainable shifting paths or rather of pivoting angles relative to the respective active travel carried out on the actuator can be achieved wherein this can take place in linear as well as non-linear manner with respect to the respective active travels of the actuator.

Activation of the actuator takes place whenever there is no detection and initiation to occur within the defined time intervals, thus the respective actuator is inactive every time when ultrasonic waves are emitted, and retroreflective ultrasonic waves are detected. Consequently, time synchronous drive of the ultrasonic transmitting and receiving element and the actuator should be allowed to take place with an electronic control and evaluation unit. With such an electronic control and evaluation unit the respective actuator can be manipulated such that a particular predetermined travel path is implemented which results in defined pivoting about a predeterminable angle or in shifting with a predetermined path of the respective acoustic element and ultrasonic transmitting and receiving element, respectively.

At least, the detection of retroreflective ultrasonic waves should take place by means of an electronic control and evaluation unit such that not only the respective position coordinates of the entire device relative to the respective body/component part but also allocation to the acoustic irradiation angle each selected or to the respective position of the focal point can taken into account for the respective individual measurement.

It is also possible to perform each pivoting and shifting about and along of more than one axis, respectively, such as by means of suitable gears. However, with appropriate support of the ultrasonic transmitting and receiving element and acoustic element, respectively, this effect can also be achieved in two axes.

In this case it may be of advantage for particular selected surface areas of a respective acoustic element on which the ultrasonic waves impinge to be formed in a discriminating manner. Thus, surface areas can be formed with different inclination angles or rather with a different curvature.

Thus, it is possible for the one half of an acoustic element and for the second half of this acoustic element to be formed inclined and/or curved in various manner. An acoustic element such formed is then allowed to be reciprocatingly pivoted about that axis in which the respective separation line of the two halves is also situated, such that ultrasonic waves exclusively impinge upon one half of an acoustic element such formed, on the one hand, and after pivoting in the opposite direction the ultrasonic waves then impinge exclusively upon the other half of such an acoustic element. In these cases, reciprocatingly pivoting of the acoustic element between two final positions is then allowed to occur having a suitable actuator such that “switch-over” is achievable more or less.

If such an acoustic element has been positioned and held in such a final position, pivoting and shifting according to the invention, respectively, is then allowed to occur in order to be able carrying out selective influence of the respective acoustic irradiation angle or positioning the focal point for an individual measurement during the non-destructive inspection of a component part.

With the above indicated embodiments, it will be apparent that a device according to the invention is very advantageously and flexibly applicable, and the non-destructive inspection can be carried out on the most variously formed component parts in a universal form with one individual configuration of such a device. The cost for the fabrication is only slightly increased compared with conventional standard ultrasonic testers since, e.g., it is allowed to be drawn on conventional ultrasonic transmitting and receiving elements, and an electronic control and evaluation unit anyhow being available has to be slightly modified only.

As for the rest, the effects of the conventional transceiver array probes can be obtained with the device according to the invention as well, wherein a distinctly greater acoustic irradiation angle range of 40° to 80°, however, with respect to the vertical line can be covered on the surfaces of the body/component part.

In addition, detection of longitudinal waves and transverse waves as well can occur with an increased sensitivity.

In the following, the invention will be explained in more detail by way of example in which

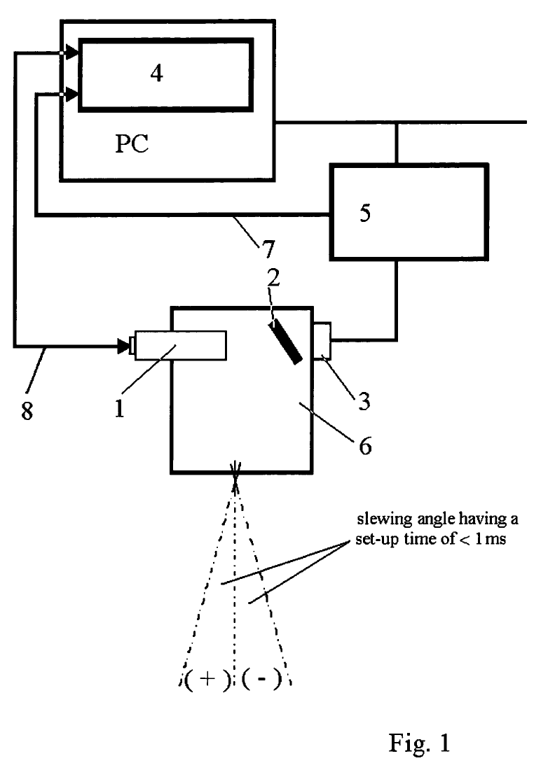

FIG. 1 shows a block diagram of an example of the device according to the invention in a diagrammatic form.

In FIG. 1 a block diagram of a device according to the invention is shown in an embodiment. At the same time, a commercial ultrasonic transmitting and receiving element 1 is housed on one side inside a testing head 6 such that ultrasonic waves can be emitted in parallel to the respective surface of a body/component member not shown herein from the ultrasonic transmitting and receiving element 1. The ultrasonic waves emitted from the ultrasonic transmitting and receiving element 1 impinge upon an acoustic element 2 reflecting ultrasonic waves which is formed herein as a parallel-sided plate, and which are reflected from the respective surface towards the surface of the body/component part. The space of the testing head 6 in which the movable elements are located is filled with a liquid of high acoustic impedance. Such a liquid, for example, can be a metal (e.g. mercury) being molten at operating and application temperatures, respectively, or a metal alloy.

Thus, at least such parts of the ultrasonic transmitting and receiving element which emit and detect the ultrasonic waves should be contacted with the liquid. Acoustic elements may be totally immersed in the liquid.

Since the ultrasonic transmitting and receiving element 1 is intermittently operated, thus emitting momentary ultrasonic waves, and subsequently to this such ultrasonic waves which are retroreflective from the respective component part and then reflected from the acoustic element 2 upon the ultrasonic transmitting and receiving element 1 are detected, respective time synchronous drive of the ultrasonic transmitting and receiving element 1 is required from the electronic control and evaluation unit 4 which takes part by means of a connecting line 8 being commercially as well.

With the embodiment shown in FIG. 1, adjustment of different acoustic irradiation angles shall be enabled. For this purpose, the reflecting acoustic element 2 is swivel-supported about an axis of rotation which herein is orthogonally directed into the plane of drawing. Swivelling the reflecting acoustic element 2 is achieved with the voice coil actuator 3 wherein selectively predetermined pivoting angles of the reflecting acoustic element 2 can be adjusted for particular desired acoustic irradiation angles.

For defined swivelling the reflecting acoustic element 2, an electronic control 5 is available which is illustrated herein separately. However, this electronic control 5 can also be integral constituent of a complete electronic control and evaluation unit.

By means of the connecting line 7, it shall be indicated that a correspondingly suitable and time synchronous drive of the voice coil actuator 4 can take place through the electronic control 5 such that swivelling the reflecting acoustic element 2 occurs at times only whenever no emission and detection of ultrasonic waves will be performed with the ultrasonic transmitting and receiving element 1.

At least at times in which a detection of retroreflective ultrasonic waves from the respective body/component part is occurring, the respective pivoting angle or another proportional value such as the respective acoustic irradiation angle is also allocated to the respective detected measuring signals such that this can be additionally considered during the evaluation of the measuring data.

But instead of the reflecting acoustic element 2 being relatively simple formed and used with this embodiment, acoustic elements as they have already been explained in the general part of the description can also be used. In addition, a linear translational shifting of respective acoustic elements is also possible by means of a voice coil actuator 3, wherein this should then take part preferably in parallel to the surface of the respective body/component part with the shown embodiment.

1. A device for the ultrasonic inspection in which an ultrasonic wave transmitting and receiving element is housed in a testing head mountable on the upper surface of a body, characterized in that said ultrasonic wave transmitting and receiving element (1) and/or one acoustic element (2) reflecting, focussing and/or deflecting an emitted beam of ultrasonic waves is pivotable about at least one axis of rotation, and/or is movable laterally along at least of one axis by means of at least one actuator (3).

2. A device according to claim 1, characterized in that said acoustic element (2) has a surface reflecting ultrasonic waves.

3. A device according to claim 1, characterized in that said acoustic element (2) has a concavely curved surface reflecting ultrasonic waves which reflects said ultrasonic waves.

4. A device according to claim 3, characterized in that said surface is curved spherically.

5. A device according to claim 1, characterized in that said acoustic element (2) is an acoustic lens or an acoustic prism.

6. A device according to claim 1, characterized in that said actuator is a voice coil actuator.

7. A device according to claim 1, characterized in that said it can be operated with a shot repetition frequency of greater than 750 Hz.

8. A device according to claim 1, characterized in that a space inside of said testing head in which parts of said ultrasonic wave transmitting and receiving element (1) are housed is charged with a liquid of high acoustic impedance.

9. A device according to claim 1, characterized in that said ultrasonic wave transmitting and receiving element (1) and said actuator (3) are addressable in a time synchronous manner by means of an electronic controlling and evaluation unit (4, 5).

10. A device according to claim 1, characterized in that said actuator (3) and said acoustic element (2) are connected to each other via a lever element or a gear.

11. A device according to claim 1, characterized in that said surface area of said acoustic element (2), which said ultrasonic waves impinge on, are inclined and/or curved differently.
